(19) United States
(12) Patent Application Publication
(10) Pub. No.: US 2014/0320121 A1
(43) Pub. Date: Oct. 30, 2014

(54) MEASUREMENTS OF EARTH'S MAGNETIC FIELD INDOORS

(71) Applicant: INDOORATLAS OY, Oulu (FI)

(72) Inventors: Mikko Perttunen, Oulu (FI); Janne Haverinen, Kiviniemi (FI)

(21) Appl. No.: 13/871,612

(22) Filed: Apr. 26, 2013

(51) Int. Cl. G01R 33/02

(52) U.S. Cl. CPC G01R 33/02
USPC 324/244

(57) ABSTRACT

There is provided an apparatus, comprising: at least one processor and at least one memory including a computer program code, wherein the at least one memory and the computer program code are configured, with the at least one processor, to cause the apparatus at least to: perform a set of Earth's magnetic field, EMF, measurements inside a building, wherein each EMF measurement result represents at least one of a magnitude and a direction of the EMF in the building;
store the set of EMF measurement results off-line into a memory buffer coupled to the apparatus; and upon detecting a predefined triggering condition, cause a transfer of the stored set of EMF measurement results to a database entity.

### FIELD

The invention relates generally to indoor positioning systems. More particularly, the invention relates to application of measurements of Earth's magnetic fields.

### BACKGROUND

It may be of importance to track person's movements when the person is inside a building. However, a well-known outdoor positioning system employing a global positioning system (GPS) or any other satellite based system may not work inside a building due to lack of reliable reception of satellite coverage. Therefore, a positioning technique utilizing Earth's magnetic fields (EMF) indoors has been developed as one possible option for indoor location discovery. This type of location discovery applies, for example, a magnetic field strength measured by a positioning device.

### BRIEF DESCRIPTION OF THE INVENTION

According to an aspect of the invention, there are provided apparatuses as specified in claims 1 and 16.

According to an aspect of the invention, there is provided a method comprising: performing a set of Earth's magnetic field, EMF, measurements inside a building, wherein each EMF measurement result represents at least one of a magnitude and a direction of the EMF in the building; storing the set of EMF measurement results off-line into a memory buffer coupled to the apparatus; and upon detecting a predefined triggering condition, causing a transfer of the stored set of EMF measurement results to a database entity.

According to an aspect of the invention, there is provided a method comprising: storing an indoor Earth's magnetic field, EMF, data representing at least one of magnitude and direction of the EMF in a building; causing a reception of a set of stored EMF measurement results from a mobile apparatus, wherein each EMF measurement result of the set represents at least one of the magnitude and the direction of the EMF in the building and is determined and stored by the mobile apparatus moving in the building; comparing the received set of EMF measurement results to the stored EMF data; and determining, on the basis of the comparison, information about movements of the person associated with the mobile apparatus.

According to an aspect of the invention, there is provided a computer program product embodied on a distribution medium readable by a computer and comprising program instructions which, when loaded into an apparatus, execute any of the methods mentioned.

According to an aspect of the invention, there is provided a computer-readable distribution medium carrying the above-mentioned computer program product.

According to an aspect of the invention, there is provided an apparatus comprising means for performing any of the embodiments as described in the appended claims.

Embodiments of the invention are defined in the dependent claims.

### LIST OF DRAWINGS

In the following, the invention will be described in greater detail with reference to the embodiments and the accompanying drawings, in which

FIG. 1 presents a floor plan of a building;

FIGS. 2A to 2C show a positioning device and an example measured magnetic field vector;

FIGS. 3A and 3B show methods according to some embodiments;

FIG. 4 shows a possible path traveled by a person in the building;

FIG. 5 shows an example for performing a set of EMF measurements, according to an embodiment;

FIG. 6 shows generation of the location estimate, according to an embodiment;

FIG. 7 shows an example for performing a set of inertial measurements, according to an embodiment;

FIG. 8 shows possible triggering conditions, according to some embodiments;

FIGS. 9A and 9B show some embodiments related to a case where the building is a shop, according to some embodiments;

FIG. 10 show some embodiments related to access rights of the mobile apparatus, according to some embodiments; and

FIGS. 11 and 12 illustrate apparatuses according to embodiments.

### DESCRIPTION OF EMBODIMENTS

The following embodiments are exemplary. Although the specification may refer to “an”, “one”, or “some” embodiment(s) in several locations of the text, this does not necessarily mean that each reference is made to the same embodiment(s), or that a particular feature only applies to a single embodiment. Single features of different embodiments may also be combined to provide other embodiments.

In order to enable positioning, a GPS based location discovery and/or tracking is known. The GPS location discovery may not, however, be suitable for indoors due to lack of satellite reception coverage. For indoor based location tracking, RF based location discovery and location tracking may be used. In such system, a round trip time of the RF signal, or the power of the received RF signal, for example, may be determined to an indoor base station to which the user device is connected to. This type of location tracking may suffer from a lack of accuracy, for example, when the user gets located by two different RF base stations. Also, the coverage area of one base station may be wide resulting in poor accuracy. Some other known positioning measures, which may be applicable indoors, include machine vision, motion sensor and distance measuring, for example. However, these may require expensive measuring devices and equipment mounted throughout the building. As a further option, the utilization of Earth's magnetic field (EMF) may be applied.

The material used for constructing the building may affect the EMF measurable in the building and also the EMF surrounding the building. For example, steel, reinforced concrete, and electrical systems may affect the EMF. The EMF may vary significantly between different locations in the building and may therefore enable accurate location discovery and tracking inside the building based on the EMF local deviations inside the building. On the other hand, the equipment placed in a certain location in the building may not affect the EMF significantly compared to the effect caused by the building material, etc. Therefore, even if the layout and amount of equipment and/or furniture, etc., change, the measured EMF may not change significantly.

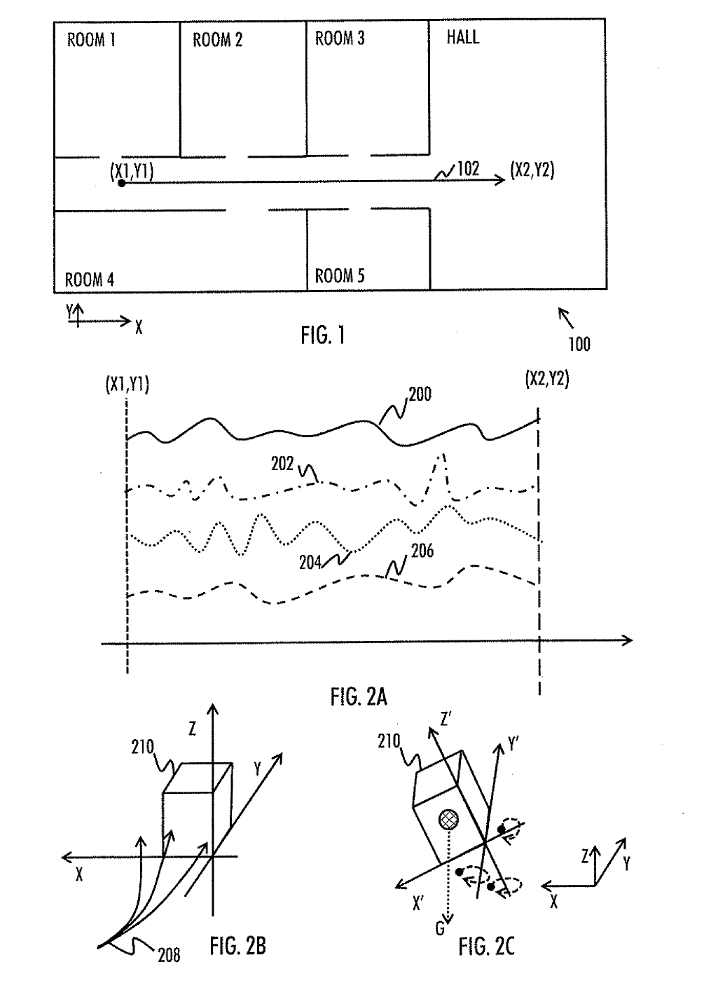

An example of a building 100 with 5 rooms, a corridor and a hall is depicted in FIG. 1. It is to be noted that the embodiments of the invention are also applicable to other type of buildings, including multi-floor buildings. The floor plan of the building 100 may be represented in a certain frame of reference. A frame of reference may refer to a coordinate system or set of axes within which the position, orientation, etc. of a positioning device are measured, for example. Such a frame of reference of the building in the example of FIG. 1 may be an XY coordinate system, also known in this application as the world coordinate system. The coordinate system of the building 100 may also be three dimensional when vertical dimension needs to be taken into account. The vertical dimension is referred with Z, whereas X and Y together define a horizontal two-dimensional point (X,Y). In FIG. 1, the arrow starting at a point (X1, Y1) and ending at a point (X2, Y2) may be seen as a path 102 traversed by a user associated with an EMF positioning device. The vertical Z dimension is omitted for simplicity. The positioning device is detailed later, but for now it may be said, that the positioning device may comprise a magnetometer or any other sensor capable of measuring the EMF, such as a Hall sensor or a digital compass. The magnetometer may comprise at least one orthogonal measuring axis. However, in an embodiment, the magnetometer may comprise three-dimensional measuring capabilities. Yet in one embodiment, the magnetometer may be a group magnetometer, or a magnetometer array which provides magnetic field observation simultaneously from multiple locations spaced apart. The magnetometer may be an accurate sensor capable to detect any variations in the EMF. In addition to the strength, also known as magnitude, intensity or density, of the magnetic field (flux), the magnetometer may be capable of determining a three-dimensional direction of a measured EMF vector. To this end, it should be noted that at any location, the Earth's magnetic field can be represented by a three-dimensional vector. Let us assume that a compass needle is tied at one end to a string such that the needle may rotate in any direction. The direction the needle points, is the direction of the Earth's magnetic field vector.

As said, the magnetometer carried by a person in the positioning device traversing the path 102 in FIG. 1 is capable of determining the three-dimensional magnetic field vector. Example three components of the EMF vector as well as the total strength are shown in FIG. 2A throughout the path 102 from (X1, Y1) to (X2, Y2). The solid line 200 may represent the total strength of the magnetic field vector and the three other lines 202 to 206 may represent the three component of the three dimensional magnetic field vector. For example, the dot-dashed line 202 may represent the Z component (vertical component), the dotted line 204 may represent the X component, and the dashed line 206 may represent the Y component. From this information, the magnitude and direction of the measured magnetic field vector may be extracted. FIG. 2B shows how the Earth's magnetic field 208 may be present at the location of an object 210, such as the positioning apparatus. In FIG. 2B, the object 210 is oriented in the three-dimensional space (XYZ) according to the frame of reference of the building. However, typically the object is moving and the three-dimensional orientation of the object 210 may vary from the frame of reference of the building as shown in FIG. 2C. In this case, the three-dimensional frame of reference is not for the building but for the object 210. Such frame of reference may be denoted with X′, Y′, and Z′ corresponding to rotated X, Y, and Z of the world coordinate system. The G vector in FIG. 2C denotes the gravitational force experienced by the object 210.

In location tracking/discovery of positioning device, or any target object moving in the building 100, each EMF vector measured by the positioning device carried by a person may be compared to existing information, wherein the information may comprise EMF vector strength and direction in several locations within the building 100 or within a plurality of buildings. The information may thus depict an indoor Earth's magnetic field map. As the amount of data in the EMF map, typically covering many buildings, may be large, the EMF map may be stored in a database entity or a server instead of the mobile positioning device having limited computational capabilities. The positioning device may thus transmit each EMF measurement result to the database server in a network, i.e. to a cloud, which performs the comparison against the EMF map. As a result, the database server may then return a location estimate to the positioning device. However, such acquisition of the location estimate may be slow. This may be because typically the database server requires several EMF measurements to provide a reliable location estimate for the positioning device. Further, in some situations, there may not be any network available for the positioning device due to the environment or due to the characteristics of the positioning device. This approach also consumes the battery of the device significantly as measurements are repeatedly transmitted to the cloud.

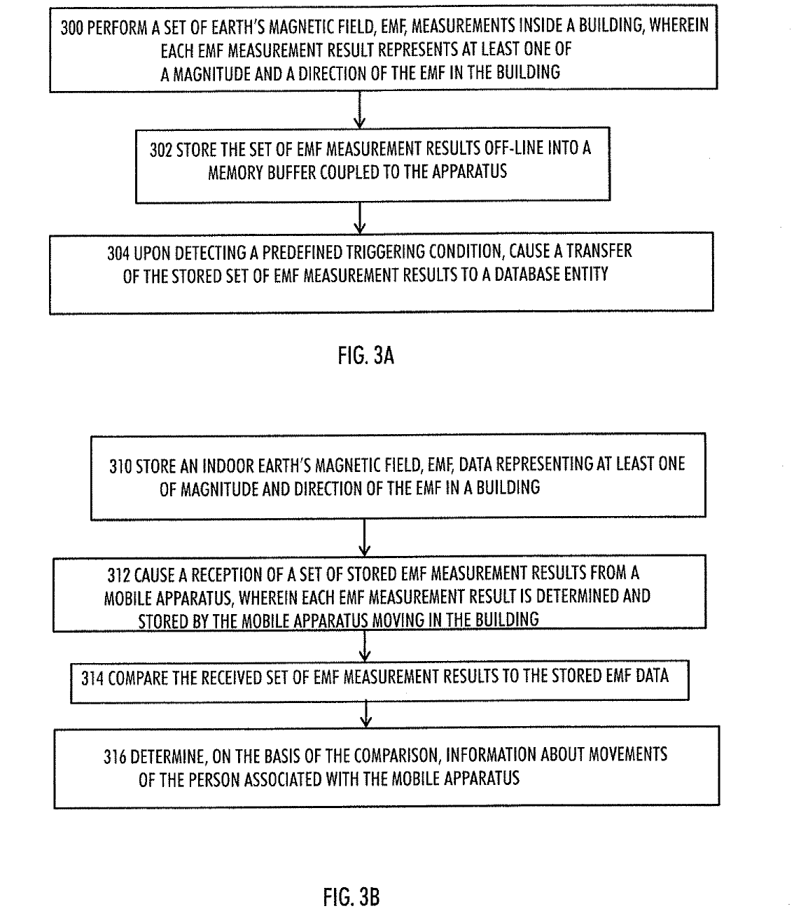

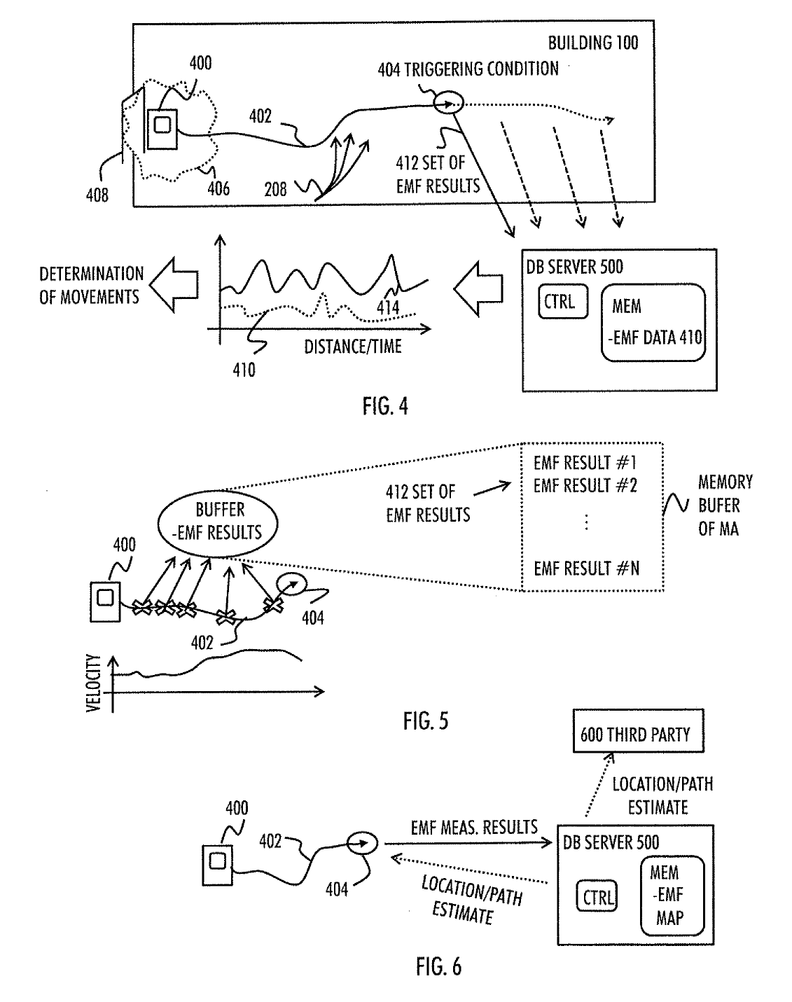

As shown in FIGS. 3A and 4, it is proposed that a mobile apparatus (MA) 400 performs, in step 300, a set of EMF measurements inside the building 100. For example, the MA 400 may be moving along the path 402 in the building 100. As indicated earlier, each EMF measurement result may represent at least one of a magnitude and a direction of the EMF 208 in the building 100. However, instead of transmitting each of the EMF measurement results (such as the measured EMF vector values) to the database entity 500 individually and directly, the MA 400 may, in step 302, store the set 412 of EMF measurement results off-line into a memory buffer coupled to the MA 400. The memory buffer may be comprised in the MA 400. Thereafter, in step 304, upon detecting a predefined triggering condition 404, the MA 400 causes a transfer of the stored set 412 of EMF measurement results to a database entity 500. It may be noted that in case the predefined triggering condition 404 does not take place, the stored EMF results need not be transferred at all. In this case, there may be a predetermined time window within which the triggering event 40 needs to occur. In case it does not occur, the offline buffer may be flushed with respect to the stored EMF measurement results. The transfer may be a direct transfer from the MA 400 to the database entity 500, or the transfer may take place via a third party. Looking at FIG. 4, the solid path represents the part during which EMF is measured and the results are continuously stored off-line to the memory buffer. The circle represents the detection of the predefined triggering condition 404 at which point the transmission of the stored set of EMF results to the database entity 500 takes place.

It should also be noted that in an embodiment, the database entity 500 locates in the MA 400. Then the transfer of the content of the offline buffer may require internal transfer of data within the MA 400. However, in another embodiment, the database entity 500 is comprised in a database server in the network, such as in the Internet. In this case, the transfer of the content of the offline buffer may require wireless transmission of data to the network. For simplicity of the specification, the latter option is assumed in the following specification.

Such storing of the set 412 of the EMF results may be advantageous because later, as will be described, the stored set 412 of EMF results may be used for quickly acquiring a location estimate of the MA 400, for example, or for some other purpose. Further, in some cases there is no access available to the database entity 500 in the network. Typically in such case, the MA 400 may not be able transmit the measured EMF vectors to the database 500 and, thus, discard any measured EMF vector. Alternatively, in such lack of network access case, the MA 400 may not be able to turn on or apply any location estimation or navigation software. However, according to the proposed manner, the software may be switched on and the measured EMF vectors may be stored off-line to the memory buffer of the MA 400 for further use. In an embodiment, the MA 400 is in an off-line state while performing the EMF measurements. This may be due to the lack of network coverage, for example, or due to power/battery saving of the MA 400, for example. In an embodiment, la the MA 400 is otherwise in an on-line state but with respect to the EMF measurement based software applications the MA 400 is in the off-line state. This may advantageously save battery of the MA 400.

In an embodiment, the MA 400 may, after detection of the triggering condition 404, continue performing EMF measurements and possibly transmit the EMF results individually to the database entity 500 for enabling location tracking of the MA 400 as shown in FIG. 4 with the dashed arrows. However, in another embodiment, after detection of the predefined triggering condition 404, the MA 400 may stop performing further EMF measurements, or perform further EMF measurements but instead of individually transmitting the EMF results to the database entity 500, the MA 400 may store the EMF results off-line to the memory buffer for further use. In such case the MA 400 may transmit another set of stored EMF measurement results to the database entity 500 once the triggering condition is met the next time. Thus, in this embodiment, the database entity 500 is not continuously updated with measurement results but only occasionally. The database entity 500 may then, upon receiving another set of stored results, perform some processing of the received set of results, such as determining the location estimate of the MA 400. The database entity 500 need not continuously (online) perform the processing of the received EMF results, but only occasionally upon reception of the set of results. As a result, the database entity 500 may use computationally more complex algorithms for the location estimation as continuous, real-time estimation is not needed. Further, the database entity 500 may have more EMF measurements results available for each location estimation process. This may advantageously enable the location estimation to be performed with a simpler data. For example, the location estimation may be performed on the basis of the magnitude information only, without any need for orientation correction of the measuring mobile apparatus, for example.

In an embodiment, the person associated with the MA 400 may activate the process in which the MA 400 performs the set of EMF measurements and stores the corresponding EMF results. This may happen via a user interface of the MA 400, for example. However, in another embodiment, the MA 400 may automatically determine that the MA 400 is or is about to be inside the building 100 upon detecting a proximity to a reference location 406. The reference location 406 may be a door 408, an elevator, or any other location inside the building 100. After such detection, the MA 400 may automatically start to perform the set of EMF measurements without further user instruction. In another embodiment, after such detection, the MA 400 may prompt the person about whether or not the MA 400 should start performing the set of EMF measurements. Thus, a verification from the user/person associated with the MA 400 may be required.

In an embodiment, the detection of proximity to the reference location 406 may be based on at least one of the following: a near field communication (NFC), infra-red (IR) communication, Bluetooth signal, radio frequency identification (RFID), a service set identifier (SSID), basic SSID, manual input. There may, for example, be a proximity radio frequency (RF) signal being transmitted in the front door 408 of the building 100. The proximity RF signal may be directed towards the inside of the building 100. As the MA 400 detects the proximity RF signal, the MA 400 may determine that the MA 400 now entered the building 100 and, consequently, start performing the EMF measurements and storing the corresponding EMF results to the buffer.

As one further possibility, satellite navigation, such as the GPS, may be applied for detecting the proximity to the reference location 406. For example, a detection of specific geolocation defined by the GPS coordinates may be used to trigger the start of the EMF measurements. For example, the approach of the person carrying the MA 400 towards the building 100 may be detected on the basis of the GPS. Then the EMF measurements may be triggered on. This may be advantageous so that the person may later use the stored EMF measurements to acquire an estimate of traveled path, including an entry door used for entering the building 100.

In an embodiment, the MA 400 applies predetermined rules for the EMF results stored in the memory buffer. As one example rule, it may be required that each EMF result stored in the memory buffer corresponds to an EMF measurement performed within a certain time window. Such time window may comprise the last ten minutes, for example. In an embodiment, a storing protocol applied by the MA 400 applies a first-in first-out method, also known as a circular or ring buffer, in which the oldest recorded EMF result is first one to be dropped before storing a new EMF result.

In an embodiment, the set of EMF measurements comprises at least a predetermined number of the EMF measurements, denotes performing EMF measurements for at least a predetermined time duration (such as at least one minute), or denotes performing EMF measurements for at least as long as the person associated with the MA 400 has traveled a predetermined distance (such as 10 meters), for example. This distance may be observed by detecting the steps of the person, for example. In an embodiment, the EMF measurements to be comprised in the set are performed for at least as long as the predetermined triggering condition is met.

In an embodiment, as shown in FIG. 5, the MA 400 may perform the set of EMF measurements according to a predefined periodicity in time domain. For example, the MA 400 may perform one EMF measurement every other second. In FIG. 5, a cross denotes an EMF measurement performed. Thus, the measurement locations are evenly distributed in time domain. In case, the person associated with the MA 400 moves with a varying speed/velocity as shown in FIG. 5, the EMF results may be correspond to unevenly distributed locations in the path.

FIG. 5 also shows that the set 412 of EMF results are stored in the buffer off-line, instead of transmitting them individually to the database entity 500. The memory buffer of the MA 400 may be continuously updated with the latest EMF measurement results. Thus, the set 412 of EMF measurement results comprises a plurality of EMF measurement results, such a EMF vector values.

Let us then take a look at the FIG. 3B which depicts a method applied by the database entity 500. In step 310 and as shown in FIG. 4, the database entity/entity 500 may store indoor EMF data representing at least one of a magnitude and a direction of the EMF in the building 100. However, it should be noted here that the stored EMF data may not be location specific. In other words, the database entity 500 need not necessarily know to which location/path the EMF data corresponds to. However, in another embodiment, the EMF data comprises the EMF map for the building 100, and possibly to other buildings. As implied by the word “map”, the EMF map comprises location specific data: each location in the map is associated with a certain EMF value (either magnitude or direction), for example. In yet one embodiment, the EMF data comprises a reference EMF sequence 410 which may or may not be location specific.

In step 312, the database entity receives the set 412 of the stored EMF measurement results from the MA 400. This step takes place once the MA 400 has detected the predetermined triggering condition 404, as shown in FIG. 4. The set 412 comprises a plurality of EMF measurements results, such as tens or hundreds of individual EMF results, each corresponding to a specific EMF measurement performed by the MA 400. Thus, the database entity 500 may generate a sequence 414 of the set 412 corresponding to the EMF results. The sequence 414 may depict, for example, the EMF magnitudes as measured by the MA 400.

In step 314, the database entity 400 may then compare the received set 412 of EMF measurement results (such as the sequence 414) to the stored EMF data 410, and in step 316, determine, on the basis of the comparison, information about movements of the person associated with the MA 400. As one possible outcome, in case the received set 412 of EMF measurement results and the stored EMF data 410 match, the database entity 500 may determine that the person has been moving along the same path or is at the same location as represented by the reference sequence 410. Even though not necessarily being able to determine the exact location of the person in the building 100 (in case no location specific EMF data is stored or available), the fact that the received set 412 of EMF results match or do not match with the stored EMF data may be enough for indicating enough about the movements of the person in the building 100.

In an embodiment, the EMF data 410 comprises location specific EMF data 410 for the building 100. In this case, the database entity 500 may be able to determine at least one of the following on the basis of the comparison: a location estimate of the MA 400, a path estimate of a path which the MA 400 has traveled in the building 100. Imagine, for example, a scenario in which a person associated with the MA 400 walks into the building 100. In prior art, in case the person gets lost in the building 100, the person may activate an on-line location estimation application, which may output a location estimate (based on EMF measurements) of the person to a screen of the MA 400, for example. However, before obtaining the location estimate and after activating the on-line location estimation application, the person may still need to be move for at least some meters so that the on-line location estimation application (and more particularly, the database entity 500 with which online location estimation application communicates) may provide a reliable initialization of the location estimate to the person. This causes delays to the acquisition of the location estimate and is an undesired task for the person associated with the MA 400.

According to the proposed solution, the MA 400 may have already performed the set of EMF measurements and stored the set 412 of EMF measurements results off-line to the memory buffer. After activating the on-line location estimation application (which may in this embodiment be seen as the triggering condition 404), the stored set 412 of EMF measurement results may be at once transmitted to the database entity 500. Thus, the database entity 500 may immediately obtain EMF data which may be used for providing the reliable location estimate. Thus, after activating the on-line location estimation application, the person substantially immediately obtains the location estimate from the database entity 500 without the person needing to move in the building. Thus the location/path estimate is in this case based on the stored set of EMF results.

This is shown further in FIG. 6 in which the MA 400 moves along the path 402 and once the triggering condition 404 (e.g. the activation of the on-line location estimation application) is detected, the MA 400 transmits the stored EMF measurement results to the database entity 500. The database entity 500 may then determine the location estimate and or the path estimate. In one embodiment, the database entity 500 may transmit the location estimate and/or the path estimate to the mobile apparatus, as shown with the dotted line between the database entity 500 and the MA 400. In this way, on-line location estimation application of the MA 400 is able to receive the location/path estimate based on the stored set 412 of EMF measurement results.

In another embodiment, as shown with a dotted arrow between the database entity 500 and a third part entity 600, the database entity 500 may transmit the determined location/path estimate to the third party 600 for further analysis or use. Such third party entity 600 may be, for example, shop/supermarket customer behavior analysis software or security control software, as will be described later. Thus, the database entity 500 need not necessarily transmit the location/path estimate to the MA 400.

In an embodiment, the estimate is based only on the transmitted set 412 of EMF measurement results and not on any other EMF measurements with respect to the MA 400. In other words, the database entity 500 may establish the estimate prior to processing any new EMF measurement results with respect to the mobile apparatus. Thus, even though the MA 400 moves forward after transmission of the EMF measurement results to the database entity 500 and possibly performs (and transmits) new EMF measurement results to the database entity 500, the determined location/path estimate may be based solely on those EMF measurement results 412 which have been stored in the off-line buffer and transmitted to the database entity 500 upon the triggering condition 404 is met. It should be noted that the database entity 500 may apply some other information than the EMF related information, such as information related to the movements of the MA 400 for the determination of the estimate, as will be described later.

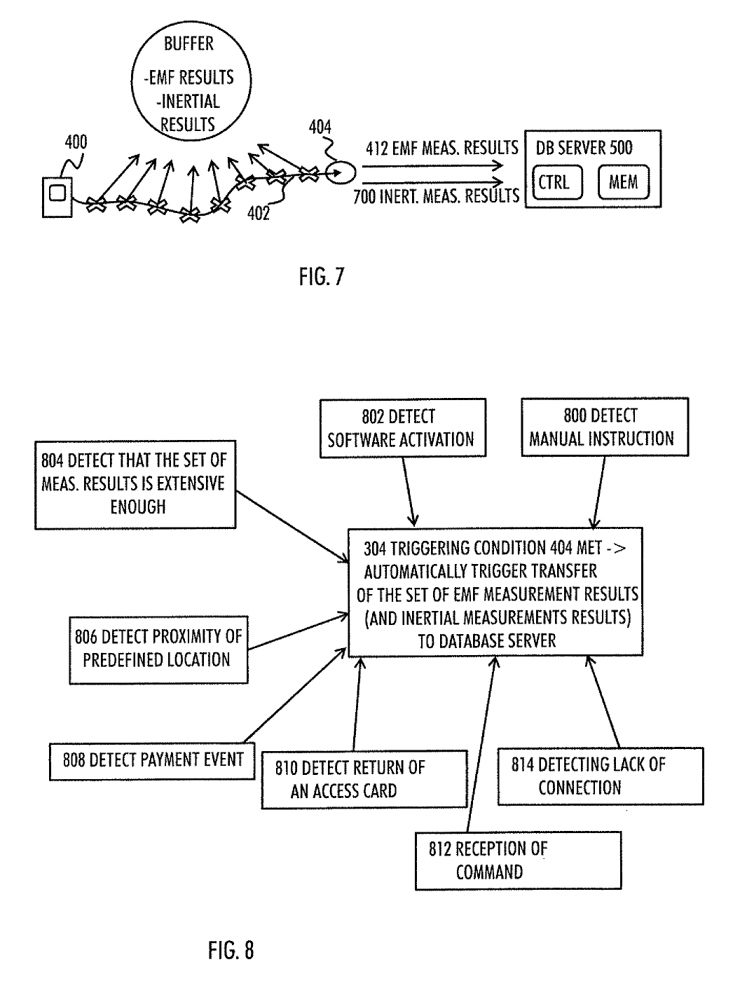

In an embodiment, as shown in FIG. 7, the MA 400 may, in addition to performing the EMF measurements, perform inertial measurements while moving in the building 100. Each inertial measurement result represents at least one of the following with respect to the movement of the MA 400: velocity (either angular or linear), acceleration, orientation, distance traveled, stride-related information (e.g. walking/running steps taken). The inertial measurements may be performed with corresponding sensors, such as accelerometers, gyroscopes, and/or other inertial measurement units (IMU) known to a skilled person. The orientation may refer to the three-dimensional orientation of the MA 400 with respect to, e.g., the building coordinates (such as to the frame of reference of the floor plan). The stride related information may imply whether or not the MA 400 is moving and also what the speed of the movement is.

The MA 400 may further store the plurality of inertial measurement results into the off-line buffer coupled to the MA 400. This is shown in FIG. 7 in which the MA 400 stores, not only the EMF measurement results, but also the inertial measurement results to the buffer each time a measurement is performed. A cross marks an EMF measurement and an inertial measurement being performed. Thereafter, the MA 400 may, upon detecting the predefined triggering condition, cause a transmission of also the stored inertial measurement results 700 to the database entity 500. The database entity 500 may apply the received set of inertial measurement results 700 for the determination of the information about movements of the person associated with the MA 400. The database 500 may require inertial information in order to reliably determine the location/path estimate. It should be noted that the location estimation may apply a plurality of location hypothesis in the building 100 and obtaining information related to the movements of the person in addition to the EMF measurement results may improve the location estimation reliability and reduce the time needed for converging to the correct location estimate.

In an embodiment, the database entity 500 may apply the inertial measurement results 700 for correcting/compensating the three-dimensional orientation of the MA 400, e.g., to correspond to the frame of reference of the floor plan. Alternatively, the MA 400 may perform correction of three-dimensional orientation prior to causing the transfer of the EMF measurement results to the database entity 500. For example, in order to determine the amount of rotation about the Y-axis and about X-axis, the MA 400 may be equipped with IMU. The IMU may comprise at least one acceleration sensor utilizing a gravitational field. The IMU may optionally also comprise other inertial sensors, such as at least one gyroscope, for detecting angular velocities, for example. The acceleration sensor may be capable of detecting the gravitational force G. By detecting the acceleration component G caused by the Earth's gravitation, the PD 400 may be able to determine the amount of rotation about axis X and/or Y. The rotation about the Z-axis may be compensated by using the information given by the gyroscope, for example. For further description about the correction of the three dimensional orientation of the MA 400 may be found from U.S. patent application Ser. No. 13/739,640, the content of which is incorporated herein by reference.

In an embodiment, the MA 400/the database entity 500 may detect whether or not the apparatus is moving on the basis of the inertial measurement results 700. In one embodiment, if the MA 400 determines that the person carrying the MA 400 is not moving, the MA 400 may restrain from performing any EMF measurements. This may save the battery resources of the MA 400 as there may not be any need to perform EMF measurements while the MA 400 is not moving. It should be noted that adjacent EMF measurements which may be separated from each other in spatial domain may be more efficient and useful for the location estimation than two EMF measurements from the same location.

In an embodiment, as shown in FIG. 7, the MA 400 may determine the distance traveled on the basis of the inertial measurement results 700. This may be done with an accelerometer, for example. Thereafter, the MA 400 may perform an EMF measurement (and an inertial measurement) each time a predefined distance is traveled. Thus, the measurement locations may be evenly distributed along the path 402 in a spatial domain.

Let us then take a look at the possible triggering conditions 404 for causing the transmission of the EMF (and inertial) measurement results to the database entity 500 by referring to FIG. 8. In an embodiment, as shown with reference numeral 800, the MA 400 detects a manual instruction being given, wherein the detection of the manual instruction is the triggering condition 404. Such instruction may be given by the person associated (e.g. the user) with the MA 400. The manual instruction may be direct instruction to transmit data to the database entity 500. In an embodiment, as shown with reference numeral 802, the MA 400 detects an activation of predefined software in the MA 400, wherein the detection of the software actuation is the triggering condition 404. Such end-user software may be, e.g. the online location estimation application, a navigation application, a press of a security button, etc.

In an embodiment, the MA 400 determines at least one characteristic with respect to the stored set 412 of EMF measurement results, wherein the at least one characteristic indicates at least one of the following: time duration between the first and the last EMF measurement result, traveled distance between the first and the last EMF measurement result, the number of the EMF measurement results. Thus, the at least one characteristic may indicate how extensive the set 412 of EMF measurement results is. The MA 400 may then, as shown with reference numeral 804, detect that a predetermined criterion is met by the at least one characteristic, wherein the meeting the predetermined criterion is the triggering condition 404. Thus, thereafter, the MA 400 may automatically trigger the transfer of the stored set 412 of EMF measurement results to the database entity 500.

In an embodiment, as shown with reference numeral 806, the MA 400 detects proximity of a predetermined location, wherein the detection of the predetermined location is the triggering condition 404. Such predetermined location may be arranged, for example, to many places within the building 100 so as to ensure accurate location estimation. Example locations may include doors, intersections, entry locations to halls, or any other type of places where the person associated with the MA 400 may be assumed to need assistance in discovering himself/herself. These locations may be detected, e.g. by detecting a proximity location technique, such as NFC, IR communication, Bluetooth signal, RFID, SSID, SSID, to mention only a few. In an embodiment, the triggering condition is a detection of an increase of certain amount in a received satellite signal, such as in the GPS signal. Such increase exceeding a certain increment threshold may imply that the person carrying the MA 400 has stepped out of the building 100. In such case it may be advantageous to acquire a location estimate from the database entity 500 which estimate may indicate, e.g., the used exit door of the building 100.

Let us then take a look at an embodiment in which the building 100 is a shop, such as a supermarket. In such case, the MA 400 may detect that a payment transaction takes place, as shown with reference numeral 808, and consider that as the triggering condition 404. As a consequence, the MA 400 may automatically trigger the transfer of the EMF measurement results (and of the inertial measurement results 700) to the database entity 500 directly or indirectly. In an embodiment, the MA 400 is a mobile phone used for performing the payment. The payment may take place via NCF technology, for example. In an embodiment, the MA 400 is a shopping card, a benefit card, a credit card, or a loyalty card which is used in connection of the payment transactions. In such case, it is the card which is equipped with at least the magnetometer for performing the EMF measurements and the memory buffer for storing the results. The power needed for these functions may be taken from a power source comprised in the card. In another embodiment, the card may charge itself from the movements of the card by utilizing kinetic energy, piezo energy, energy harvester, for example.

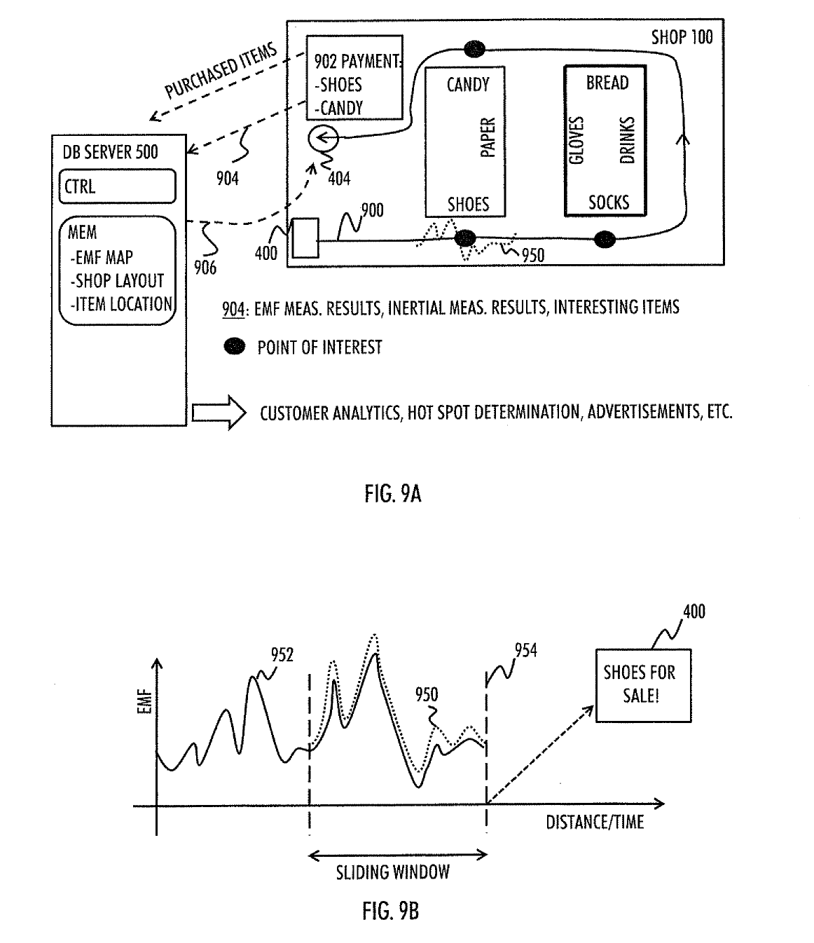

Let us consider this embodiment, in which the building is a shop, further. FIG. 9A shows a layout of a shop 100 in which the MA 400 is moving. Let us consider in this embodiment that the MA 400 is a card 400 used in connection of the payment. In this embodiment, the person associated with the card 400 moves along the path 900 in the shop 100. The black dots represent items which the person finds interesting. Thus, it is assumed that the person has, for example, stopped at the desk where shoes, socks and candy are being offered for sale. However, the person may pass the shelves with drinks and bread being sold. Further, the person may not even see some other items such as papers and gloves, as they are not located along the path 900. Let us consider these black dots as items of interest (101) in the shop 100 with respect to the person associated with the apparatus. It should be noted, although not shown, that the equipment comprised in the card 400, while moving along the path 900, performs the EMF vector measurements and possibly also the inertial measurements. Alternatively, another apparatus, such as a mobile phone, may perform the EMF and inertial measurements.

The database entity 500 may then obtain the results from the card 400 itself or the card 400 may first transfer the results into cash equipment 902 of the shop during the payment transaction, after which the cash equipment 902 may transfer the results to the database entity 500. The latter embodiment may be especially useful when the MA 400 is a card with very limited computational capabilities. The card may transfer the results and possibly some other information to the cash equipment 902 when the card is mechanically connected to the cash equipment during payment, such as during the cash equipment 902 reads the card 400.

The IOIs may be determined in a plurality of ways. In one embodiment, it is the database entity 500 which determines the IOIs on the basis of received data from the cash equipment 902, from the card 400. However, in one embodiment, the MA 400 itself may determine the IOIs in the shop. For example, it may be that the MA 400, such as a mobile phone, comprises a bar code reader. Once the person associated with the apparatus uses the MA 400 to read the bar code of an item, the MA 400 detects the identity of the item and stores the identity in the buffer of the MA 400. In one embodiment, the bar code reader is separate equipment but the identity of the item read with the separate bar code reader is detected by the MA 400, e.g. through wireless data transfer between the MA 400 and the separate bar code reader. In an embodiment, the IOIs correspond to all the items that have interested the person associated with the MA 400. These interesting items may comprise the purchased items (detectable during the payment transaction by the cash equipment 902 or by the MA 400 used for paying, for example) and/or other interesting items, such those items which the person has examined or glanced. These examined/glanced items may be detected by utilizing the bar code reader or eye glasses which record the identity/type of the items, for example. Thereafter, the MA 400 may then cause a transfer of information regarding the IOIs to the database entity 500. The transmission may be direct transmission or the information may first be transferred to the cash equipment 902, which forwards the information to the database entity 500 as shown with reference numeral 904 in FIG. 9A. At the same payment transaction, the card 400 may transfer the EMF and inertial measurement results 700 to the database entity 500 indirectly (via the cash equipment 902) or directly. Thus, performing the payment may be seen as the triggering condition 404.

In an embodiment, the eye glasses may be the MA 400. In such embodiment, for example glancing a certain 101 may be the triggering event 404 for causing the eye glasses to transmit data to the cloud. In another embodiment, the triggering event 404 may be a detectable sound, recognized voice command, recognized hand gesture, a certain type of a blink of an eye, or an image which is captured.

As such the database entity 500 acquires knowledge of the IOIs with respect the person associated with the card (or any other MA 400) in the shop 100. As shown also in FIG. 9A, the database entity 900 may store in its memory the EMF map of the building including the shop layout. Further, the database entity 900 may store in its memory the locations of the items being offered for sale in the shop 100. Thus, the database entity 500 may then determine locations in which the IOIs are being offered for sale in the shop 100. As a result, the database entity 500 now has knowledge of the locations in which the IOIs locate and, based on the EMF measurement results (and the inertial measurement results 700), knowledge of the movements of the person in the shop 100. Thereafter, the database entity 500 may perform analysis about a customer behavior of the person associated with the card 400 on the basis of the movements of the person in the shop 100 with respect to the determined locations of the IOIs. The analysis may reveal which of a plurality of predetermined consumer types the person associated with the MA 400 represents An example result of the analysis may be that the person is a type of customer which directly and purposefully goes to the IOIs. Another example result may be that the person is a type of customer which wanders around the shop 100. In one embodiment, the database entity 500 offers the knowledge of the movements and of the locations of the IOIs to a third party which performs the analysis.

In an embodiment, the MA 400 transfers the content of the buffer to the database entity 500 in case of detecting an increase of certain amount in a received satellite signal, such as in the GPS signal. This may imply that the person carrying the MA 400 has stepped out of the shop 100. Thus, the customer behavior analysis may now be performed and, therefore, the EMF measurement results may be transferred from the buffer.

In an embodiment, as the person makes the payment of the purchased items at the cash equipment 902, the cash equipment 902 acquires knowledge and generates a list of the purchased items. In the case of FIG. 9A, it is assumed that the person buys a pair of shoes and some candy. This list of purchased items may be send to the database entity 500 which in this way obtains knowledge of the list. It should be noted that the list of purchased items may be also generated by the MA 400 during payment process. The database entity 500 may then compare the list of the purchased items to the IOIs. In the case of FIG. 9A, it may be detected that the person purchased only shoes and candy but at least glanced also socks. The comparison result may be taken into account when performing the analysis about the customer behavior of the person. For example, it may be determined that the person examines only those items which he/she is purchases and the person does not make negative shopping decisions. However, as another possible analysis result, it may be detected that the person does examine many items but purchases only some of them. This may imply that there may be something wrong in the price or quality of the items being examined but not bought. Such customer analysis may be important from the point of view of the shop owners or product manufacturers, for example.

In an embodiment, the database entity 500, after determining what the IOIs with respect to the person are, the database entity 500 (or some third party entity) may cause a transmission of at least one advertisement message 906 to the MA 400 associated with the person, wherein the at least one advertisement message is related to the at least one item comprised in the IOIs. The database entity 500 may have the knowledge of the identity of the customer and, thus, the entity 500 may be able to direct the advertisement to the correct customer. The advertisement may be a mobile coupon or a mobile voucher which the person may utilize. The advertisement may be transmitted to the mobile phone (acting as the MA 400) or the advertisement may be stored to the card information which is available to the person, for example, via an internet.

In an embodiment, the advertisement is location insensitive. This may mean that the advertisement may be seen by the person at any time via the MA 400 regardless of the location of the person. For example, the MA 400 may output the advertisement immediately to the person via a display or speakers, for example.

However, in another embodiment as shown in FIG. 9B, the advertisement is location sensitive. This may mean that the database entity 500 adds metadata to the advertisement, such as an EMF fingerprint 950 (either magnitude or direction of the EMF or both). The tagged EMF fingerprint 950 may correspond to EMF vectors measurable at a specific location in the shop 100. For example, if one of the IOIs is shoes, the tagged EMF fingerprint 950 may correspond to the EMF measurable in the corridor in front of the location of the shoes, as shown in FIG. 9A as well. Such tagged EMF fingerprint 950 may be applied, by the receiving MA 400, so that the MA 400 compares the tagged EMF fingerprint 950 to EMF measurement results 952 corresponding to EMF measurements performed. The comparison may be performed constantly in a sliding window manner. In point 954, upon detecting that the tagged EMF fingerprint 950 matches with a part of the EMF measurement results 952 at least according to a predetermined matching threshold (which may be empirically or mathematically derived beforehand), the MA 400 outputs the advertisement related to the tagged EMF fingerprint 950. The output may denote displaying the advertisement in a display of the MA 400, outputting the advertisement through speakers of the MA 400, or outputting the advertisement in at least one display or a speaker of the shop, for example. Thus, in this embodiment, the customer sees the advertisement only when he/she approaches the shoe department/location. It should be noted that the MA 400 may store the advertisement and metadata in the memory of the MA 400, but display it only at the location specified by the advertiser.

After being displayed to the person, the advertisement may be deleted from the MA 400 or it may be stored in the MA 400 in order to display the advertisement in the future when the person again passes the location. In another embodiment, the advertisement may prompt the person associated with the MA 400 to respond to the advertisement, such as “I am not interested”, “Interested, but not buying the product/item at the moment”, or “Interested, I bought the advertised product/item”. After such response, the MA 400 may forward the response back to the database entity 500 so that the advertiser acquires knowledge of how the advertisements are utilized and how the customers respond to the advertisements. This may be taken into account as well when performing analysis about the customer behavior.

Let us then take a look at one more possible triggering condition 404 for causing the transfer of the EMF measurement results to the database entity 500. In an embodiment, the triggering condition 404 is a return of the MA 400, as depicted with reference numeral 810 in FIG. 8. In this embodiment, the MA 400 may be, e.g., an access card carried by person moving in the building 100. The access card 400 may comprise at least circuitries for performing the EMF measurements and possibly also the inertial measurement, a memory for storing the measurement results, and a power source (e.g. a kinetic energy power source, or a rechargeable battery).

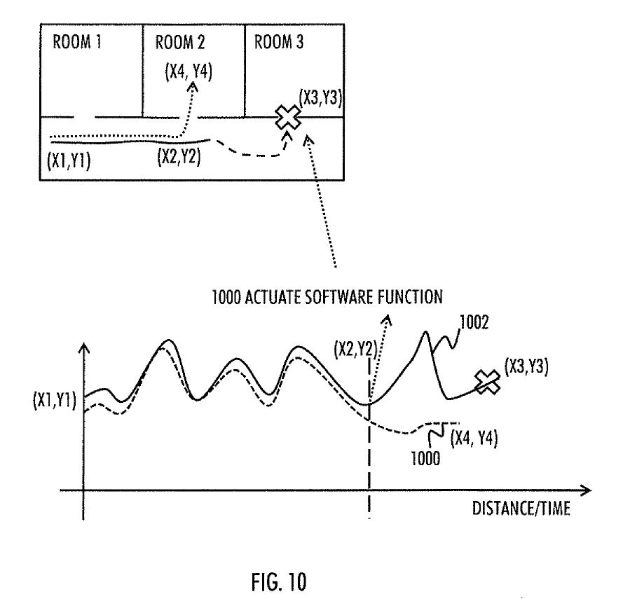

Let us look at this embodiment closer with reference to FIG. 10. Imagine that a person enters the building 100 and is given the access card which needs to be carried with the person while moving in the building. The building 100 in FIG. 10 has three rooms. The person carrying the access card (acting as the MA 400 in this embodiment) is walking in the building 100. As the person associated with the access card 400 eventually returns the card, the card may be read by a card reader. This may trigger the card to unload the stored EMF measurement results to the card reader equipment which may transmit the EMF measurement results (and possibly the inertial measurement results 700) to the database entity 900. Then the database entity 500 may detect in which rooms/locations the person carrying the access card visited.

In one embodiment, the access card may have been preconfigured with a reference fingerprint sequence 1000 representing at least one of the magnitude and the direction of the EMF for a path in the building 100, wherein the path is defined as an allowed path for the person carrying the access card. The details of the allowed path may depend on the person: Some persons may enter all of the rooms whereas some persons may not enter each of the rooms. The access card may be further configured to measure the EMF as the person in moving in the building wherein the set 412 of EMF measurement results are represented with the EMF sequence 1002. In this embodiment, it may be assumed that the person receives the access card at the point (X1, Y1). The stored reference fingerprint sequence 1000 represents an allowed path from (X1, Y1) to (X4, Y4) as marked with a dotted line in FIG. 10 of the building. As can be seen from FIG. 10, the person starts first following the allowed route which results in that the reference fingerprint sequence 1000 and the sequence 1002 corresponding to the set 412 of EMF measurement results match each other. However, in point (X2, Y2), the person decides not to follow the allowed route anymore but decides to pursue for the room #3 and the location (X3, Y3). However, as the access card may constantly or periodically compare the set 412 of EMF measurement results to the reference fingerprint sequence 1000, the deviation from the allowed route may be detected. As a result, upon detecting a difference exceeding a predetermined threshold between the set 412 of EMF measurement results and the reference fingerprint sequence 1000, the access card may determine that the person carrying the access card has deviated from the allowed path. This may cause the access card to activate a predetermined function with respect to the access card. A possible function may comprise reconfiguring access rights of the access card in the building 100 (as indicated with a cross blocking the entry to the room #3) or a transmission of indication to the security, for example. Although described so that the MA is a card, it should be noted that the embodiments of FIGS. 9A, 9B and 10 may also be performed with a mobile phone as the MA 400.

In an embodiment, as shown with reference numeral 812, the MA 400 receives a radio frequency command to discharge the content of the off-line buffer to the database entity 500. In this case, the reception of the command is the triggering condition 404. For example, imagine a mining accident, such as a collapse of a mining tunnel. Then it may be beneficial that a third party observing the accident immediately commands the plurality of MAs 400 locating in/around the mine to send the stored EMF results to the entity 500. In this way, the database entity 500 may output a location estimate which indicates the whereabouts of the MAs 400 in the mine. This may, e.g., provide a quick evaluation of which persons and how many persons are behind the collapsed tunnel.

In an embodiment, a detection of an unexpected lack or drop of a first communication connection is the triggering condition 404, as shown with a reference numeral 814. For example, in the mining environment, detecting a lack of the first communication connection may imply that an accident (e.g. a collapse of a tunnel) has taken place. The first communication connection may be a communication connection which is specific to the type of MAs 400 used in the mine. In one embodiment, the first communication connection is a cellular communication connection. In case of detecting the lack in the first communication connection, the MA 400 may automatically cause the transfer of the stored EMF measurement results to the database entity 500. In an embodiment, the transfer takes place by applying an emergency communication connection, which is different from the first connection. Such emergency communication connection may apply mine-specific infrastructure which may work even after a possible collapse of the mine tunnel, for example. The database entity 500 may then provide a location estimate of the MAs 400.

In one embodiment, the MA 400 may itself apply the stored EMF measurement results for making the location/path estimate. In such case, the database entity 500 may locate inside the MA 400. Thus, the MA 400 may internally transfer the content of the buffer to the database entity 500 inside the MA 400. The MA 400, or more particularly, the database entity 500 inside the MA 400, may also store the EMF map of the building 100 or of some other location, such as the mine environment. This embodiment may allow the MA 400 to operate in a low power mode in which the MA 400 performs the EMF measurements but does not constantly estimate the location of itself. Only when the triggering condition 404 is detected, the MA 400 computes the location/path estimate. In a further embodiment, the MA 400 may then apply the location estimate in a plurality of manners. In one possible use-case, the MA 400 (the database entity 500 in the MA 400) transfers the location estimate to a third party. This may be especially beneficial in the case of an accident in an indoor location (mine, building). As may be appreciated by a skilled person, the location of the whereabouts of the persons carrying the MAs 400 is important in such accidents.

In an embodiment, the MA 400 may have an in-built camera module for capturing images or videos, a microphone for capturing sounds, or any other unit for generating digital content. The MA 400 may, upon generating any digital content (such as videos, audio content, etc.), add the stored set 412 of EMF measurement results as metadata to the digital content. Thus, the digital content may be associated with a certain type of EMF waveform (either magnitude or direction of the measured EMF, or both) based on the set 412 of EMF measurement results. For example, the EMF waveform may be comprised as part of the format of the image. The MA 400 may then trigger a transfer of the digital content and the metadata to a predetermined target entity. Such predetermined target entity may be the database entity 500, some entity in the network, or another end-user device (e.g. another mobile apparatus). The target may be specified by the user or it may relate to the application used for generating the digital content. For example, when the digital content comprises a camera image, then the predetermined target may be different than when the digital content comprises an audio recording. The triggering of the transfer may take place manually by the person associated with the MA 400, or it may be automatic. In an embodiment, the generation of the digital content automatically causes the transfer of the digital content together with the metadata to the predetermined target.

In an embodiment, there may be a low range communication unit mounted in the building 100 for allowing calibration of the MA 400 to the correct EMF vector values. For example, the exact magnitude of the EMF may be predetermined and stored in the memory of the mounted low range communication unit. Then the MA 400 may apply this information in obtaining knowledge of how much the measured EMF magnitude deviates from the indicated, true EMV magnitude. Based on the information, a correction of the values provided by the magnetometer or calibration of the magnetometer may be in order. The low range communication may apply, for example, RFID, Bluetooth, or NFC technique. Alternatively, or in addition to, the calibration/correction may be for the direction of the EMF vector. The calibration process may also calibrate/correct data related to the direction and/or strength of the measured acceleration vector representing the direction of the gravitational force G. For this, the true value for G may have been determined for the predetermined location of the mounted low range communication unit.

Embodiments, as shown in FIGS. 10 and 11, provide apparatuses 400 and 500 comprising at least one processor 452, 502 and at least one memory 454, 504 including a computer program code, which are configured to cause the apparatuses to carry out functionalities according to the embodiments. The at least one processor 452, 502 may each be implemented with a separate digital signal processor provided with suitable software embedded on a computer readable medium, or with a separate logic circuit, such as an application specific integrated circuit (ASIC).

The apparatuses 400 and 500 may further comprise radio interface components 456 and 506 providing the apparatus 400, 500, respectively, with radio communication capabilities with the radio access network. The radio interfaces 456 and 506 may be used to perform communication capabilities between the apparatuses 400 and 500. The radio interfaces 456 and 506 may be used to communicate data related to the measured EMF vectors, to location estimation, etc. In case the apparatus 400 is comprised in a card, such as the access card or the shopping card, the apparatus 400 may comprise data transfer capabilities to physically connected equipment, such as to the payment equipment.

User interfaces 458 and 508 may be used in operating the measuring device 400 and the database entity 500 by a user. The user interfaces 458, 508 may each comprise buttons, a keyboard, means for receiving voice commands, such as microphone, touch buttons, slide buttons, etc. Again, in case the apparatus 400 is comprised in a card, such as the access card or the shopping card, the apparatus 400 may not comprise any user interface.

The apparatus 400 may comprise the terminal device of a cellular communication system, e.g. a computer (PC), a laptop, a tabloid computer, a cellular phone, a communicator, a smart phone, a palm computer, or any other communication apparatus. In another embodiment, the apparatus is comprised in such a terminal device, e.g. the apparatus may comprise a circuitry, e.g. a chip, a processor, a micro controller, or a combination of such circuitries in the terminal device and cause the terminal device to carry out the above-described functionalities. Further, the apparatus 400 may be or comprise a module (to be attached to the terminal device) providing connectivity, such as a plug-in unit, an “USB dongle”, or any other kind of unit. The unit may be installed either inside the terminal device or attached to the terminal device with a connector or even wirelessly. In another embodiment, the apparatus 400 is comprised in a card. The apparatus 500 as the database entity may locate in the network or in the MA 400. The apparatus 500 may be a server computer.

As said, the apparatus 400, such as the mobile phone or a card, may comprise the at least one processor 452. The at least one processor 452 may comprise an EMF measurement circuitry 460 for performing EMF measurements with the help of a magnetometer 470. An inertial measurement circuitry 462 may be for performing inertial measurements with the help of an IMU 472 or an odometer 474, for example. An application/advertisement activation circuitry 464 may be responsible of triggering the transfer of the stored measurement results to the database entity 500, for triggering the advertisement output or for reconfiguring the access rights of an access card, for example. A calibration & correction circuitry 466 may be responsible of performing a calibration process of a magnetometer 470 and/or correcting the acquired information from the magnetometer 470, for example.

The magnetometer 470 may be used to measure the EMF vector. There may be various other sensors or functional entities comprised in the PD 400. These may include an inertial measurement unit (IMU) 472, the odometer 474, a low range communication unit 476 for detecting the presence of a proximity communication signal, at least one camera 478, for example. A skilled person understood that these may be of use when performing the embodiments as described earlier. For example, the IMU 472 may comprise for example acceleration sensor and a gyroscope, for example. The at least one camera 478 may be used to capture images for the purposes of any of the embodiments described. The apparatus 400 may further comprise output unit 480 comprising, e.g. a display or a speaker, for outputting information such as advertisements to the person.

The memory 454 may comprise space 490 for storing the set 412 of EMF measurement results and space 492 for storing the inertial measurement results 700. Further, there may be space for a plurality of other data, such as space 494 for the reference fingerprint 950/1000, space for information about access rights, space for storing the advertisements, space for storing the list of items of interest, etc.

As earlier said, in an embodiment, the apparatus 400 comprises the apparatus 500. However, in another embodiment, the apparatus 500 is located in the network.

The apparatus 500, such as the database entity, may comprise the at least one processor 502. The at least one processor 502 may comprise several circuitries. As an example, an indoor navigation circuitry 510 for performing indoor navigation on the basis of the received set of Earth's magnetic field measurement results and EMF map. For the navigation, the memory 504 may comprise the EMF map 540, and the floor plan 542 of the building 100. The database entity 500 may indicate the position of the MA 400 within the building 100. The circuitry 510 may apply for example multi-hypothesis location estimator/tracker/filter, for example.

An application activation circuitry 514 may be responsible of causing an activation of a software function in or with respect to the PD 400. The database entity 500 may, for example, indicate to the MA 400 that an activation of a software function is in order. Such function may be for example removal of access rights, transmission of the advertisement, etc. A customer analysis circuitry 516 may be responsible for running analysis software for determining the customer type for example. The circuitry 516 may apply the information related to the movements of the person and related to the items of interest, such as the purchased items, when performing the analysis, as explained earlier. A calibration & correction circuitry 518 may be responsible of causing or co-operating in a calibration process of a magnetometer 470 of the MA 400 and/or correcting the acquired information from the magnetometer 470, for example. Further, the calibration & correction circuitry 516 may be responsible of making the orientation correction with respect to the frame of reference of the MA 400.

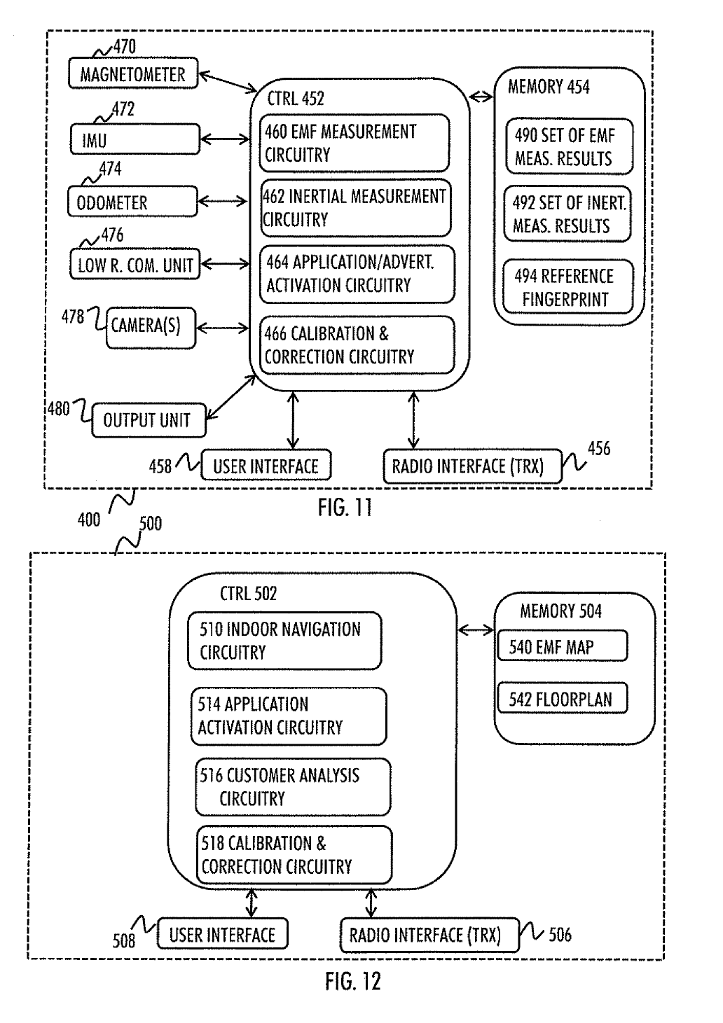

As may be understood by a skilled person from the description of the embodiments throughout the application and from FIGS. 11 and 12, the embodiments may be performed in the MA 400, in the database entity 500, or the execution of embodiments may be shared among the MA 400 and the database entity 500. The skilled person also understands that any required filtering logic may be applied to filter the EMF measurements in order to improve the accuracy.

As used in this application, the term ‘circuitry’ refers to all of the following: (a) hardware-only circuit implementations, such as implementations in only analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. This definition of ‘circuitry’ applies to all uses of this term in this application. As a further example, as used in this application, the term ‘circuitry’ would also cover an implementation of merely a processor (or multiple processors) or a portion of a processor and its (or their) accompanying software and/or firmware. The term ‘circuitry’ would also cover, for example and if applicable to the particular element, a baseband integrated circuit or applications processor integrated circuit for a mobile phone or a similar integrated circuit in a entity, a cellular network device, or another network device.

The techniques and methods described herein may be implemented by various means. For example, these techniques may be implemented in hardware (one or more devices), firmware (one or more devices), software (one or more modules), or combinations thereof. For a hardware implementation, the apparatus(es) of embodiments may be implemented within one or more application-specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. For firmware or software, the implementation can be carried out through modules of at least one chip set (e.g. procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components of the systems described herein may be rearranged and/or complemented by additional components in order to facilitate the achievements of the various aspects, etc., described with regard thereto, and they are not limited to the precise configurations set forth in the given figures, as will be appreciated by one skilled in the art.

Embodiments as described may also be carried out in the form of a computer process defined by a computer program. The computer program may be in source code form, object code form, or in some intermediate form, and it may be stored in some sort of carrier, which may be any entity or device capable of carrying the program. For example, the computer program may be stored on a computer program distribution medium readable by a computer or a processor. The computer program medium may be, for example but not limited to, a record medium, computer memory, read-only memory, electrical carrier signal, telecommunications signal, and software distribution package, for example. Coding of software for carrying out the embodiments as shown and described is well within the scope of a person of ordinary skill in the art.

Even though the invention has been described above with reference to an example according to the accompanying drawings, it is clear that the invention is not restricted thereto but can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways. Further, it is clear to a person skilled in the art that the described embodiments may, but are not required to, be combined with other embodiments in various ways.

1. An apparatus, comprising:
at least one processor and at least one memory including a computer program code, wherein the at least one memory and the computer program code are configured, with the at least one processor, to cause the apparatus at least to:
perform a set of Earth's magnetic field, EMF, measurements inside a building, wherein each EMF measurement result represents at least one of a magnitude and a direction of the EMF in the building;
store the set of EMF measurement results off-line into a memory buffer coupled to the apparatus; and
upon detecting a predefined triggering condition, cause a transfer of the stored set of EMF measurement results to a database entity.

2. The apparatus of claim 1, wherein the at least one memory and the computer program code are configured, with the at least one processor, to cause the apparatus further to:
determine that the apparatus is inside the building upon detecting a proximity to a reference location inside the building; and
automatically start to perform the set of EMF measurements.

3. The apparatus of claim 1, wherein the at least one memory and the computer program code are configured, with the at least one processor, to cause the apparatus further to:
cause a reception of a location estimate of the apparatus and/or a path estimate of a path which the apparatus has traveled in the building from the database entity, wherein the estimate is determined by the database entity and based on the transmitted set of EMF measurement results.

4. The apparatus of claim 1, wherein the at least one memory and the computer program code are configured, with the at least one processor, to cause the apparatus further to:
perform inertial measurements in the building, wherein each inertial measurement result represents at least one of the following with respect to the movement of the apparatus: velocity, acceleration, orientation, distance traveled, stride-related information;
store the plurality of inertial measurement results into the off-line buffer coupled to the apparatus; and
upon detecting the predefined triggering condition, cause a transmission of the stored inertial measurement results to the database entity.

5. The apparatus of claim 4, wherein the at least one memory and the computer program code are configured, with the at least one processor, to cause the apparatus further to:
detect whether or not the apparatus is moving on the basis of the inertial measurement results; and
upon detecting that the apparatus is not moving, restrain from performing any EMF measurements.

6. The apparatus of claim 4, wherein the at least one memory and the computer program code are configured, with the at least one processor, to cause the apparatus further to:
determine the distance traveled on the basis of the inertial measurement results; and
perform an EMF measurement each time a predefined distance is traveled.

7. The apparatus of claim 1, wherein the at least one memory and the computer program code are configured, with the at least one processor, to cause the apparatus further to:
determine at least one characteristic with respect to the stored set of EMF measurement results, wherein the at least one characteristic indicates at least one of the following: time duration between the first and the last EMF measurement result, traveled distance between the first and the last EMF measurement result, the number of the EMF measurement results;
detect that a predetermined criterion is met by the at least one characteristic; and
automatically trigger the transfer of the stored set of EMF measurement results to the database entity.

8. The apparatus of claim 1, wherein the at least one memory and the computer program code are configured, with the at least one processor, to cause the apparatus further to:
detect a reception of a wireless command from another device, wherein the command requires to according to transfer of the stored set of EMF measurement results to the database entity; and
automatically trigger the transfer of the stored set of EMF measurement results to the database entity.

9. The apparatus of claim 1, wherein the building is a shop and the at least one memory and the computer program code are configured, with the at least one processor, to cause the apparatus further to:
detect that a payment transaction takes place; and
automatically trigger the transfer of the stored set of EMF measurement results to the database entity.

10. The apparatus of claim 1, wherein the building is a shop and the at least one memory and the computer program code are configured, with the at least one processor, to cause the apparatus further to:
determine items of interest with respect to the person associated with the apparatus in the shop; and
cause a transfer of information regarding the items of interest to the database entity.

11. The apparatus of claim 1, wherein the at least one memory and the computer program code are configured, with the at least one processor, to cause the apparatus further to:
cause a reception of at least one advertisement message from the database entity, wherein the at least one advertisement message is related to at least one item of interest with respect to the person associated with the apparatus and wherein the advertisement message is location sensitive and carries an EMF fingerprint;
perform further EMF measurements and compare a sequence of the EMF measurement results to the EMF fingerprint; and
upon detecting that the sequence of the EMF measurements results match with the EMF fingerprint, cause an output of the location sensitive advertisement via the apparatus.

12. The apparatus of claim 1, wherein the at least one memory and the computer program code are configured, with the at least one processor, to cause the apparatus further to:
acquire and store a reference fingerprint sequence representing at least one of the magnitude and the direction of the EMF for a path in the building, wherein the path is defined as an allowed path for the person carrying the apparatus;
compare the set of EMF measurement results to the reference fingerprint sequence;
upon detecting a difference exceeding a predetermined threshold between the set of EMF measurement results and the reference fingerprint sequence, determining that the person carrying the apparatus has deviated from the allowed path; and
activate a predetermined function with respect to the apparatus.

13. The apparatus of claim 1, wherein the at least one memory and the computer program code are configured, with the at least one processor, to cause the apparatus further to:
generate digital content;
add the stored EMF measurement results as metadata to the digital content; and
automatically trigger a transfer of the digital content and the metadata to a predetermined target entity.

14. The apparatus of claim 1, wherein the apparatus is comprised in one of the following: an access card, a shopping card, a benefit card, a loyalty card.

15. The apparatus of claim 1, wherein the database entity is comprised in a server computer in a network.

16. A database entity, comprising:
at least one processor and at least one memory including a computer program code, wherein the at least one memory and the computer program code are configured, with the at least one processor, to cause the database entity, at least to:
store an indoor Earth's magnetic field, EMF, data representing at least one of magnitude and direction of the EMF in a building;
cause a reception of a set of stored EMF measurement results from a mobile apparatus, wherein each EMF measurement result of the set represents at least one of the magnitude and the direction of the EMF in the building and is determined and stored by the mobile apparatus moving in the building;
compare the received set of EMF measurement results to the stored EMF data; and
determine, on the basis of the comparison, information about movements of the person associated with the mobile apparatus.

17. The database entity of claim 16, wherein the at least one memory and the computer program code are configured, with the at least one processor, to cause the database entity further to:
cause a reception of a set of stored inertial measurement results from the mobile apparatus, wherein each inertial measurement result is determined and stored by the mobile apparatus in the building and represents at least one of the following with respect to the movement of the mobile apparatus: velocity, acceleration, orientation, distance traveled, stride-related information; and
apply the received set of inertial measurement results for the determination of the information about movements of the person associated with the mobile apparatus.

18. The database entity of claim 16, wherein the building is a shop, and the at least one memory and the computer program code are configured, with the at least one processor, to cause the database entity further to:
acquire knowledge of items of interest with respect the person associated with the mobile apparatus in the shop;
determine locations in which the items of interest are being offered for sale in the shop; and
performing analysis about a customer behavior of the person associated with the mobile apparatus on the basis of the movements of the person in the shop with respect to the determined locations.

19. The database entity of claim 18, wherein the building is a shop, and the at least one memory and the computer program code are configured, with the at least one processor, to cause the database entity further to:
acquire knowledge of a list of items which the person associated with the mobile apparatus purchased from the shop;
compare the list of the purchased items to the items of interest and
apply the comparison result when performing the analysis about the customer behavior of the person.

20. The database entity of claim 16, wherein the building is a shop, and the at least one memory and the computer program code are configured, with the at least one processor, to cause the database entity further to:
cause a transmission of at least one advertisement message to the person associated with the mobile apparatus, wherein the at least one advertisement message is related to at least one item comprised in the items of interest.
